(19) United States
(12) Patent Application Publication
(10) Pub. No.: US 2025/0369088 A1
(43) Pub. Date: Dec. 4, 2025

(54) Stencil mask and use thereof in lithography fabrication

(71) Applicant: University of Copenhagen, Copenhagen K (DK)

(72) Inventors: Michaela Eichinger, Copenhagen Ø (DK); Morten Kjaergaard, Copenhagen Ø (DK); Thomas Kanne Nordqvist, Copenhagen Ø (DK); András Gyenis, Copenhagen Ø (DK)

(21) Appl. No.: 18/873,862

(22) PCT Filed: Jun. 19, 2023
(86) PCT No.: PCT/EP2023/066468

§ 371 Date: Dec. 11, 2024

(30) Foreign Application Priority Data
Jun. 21, 2022 (EP) 22180214.3

(51) Int. Cl. C23C 14/04

(52) U.S. Cl. CPC C23C 14/042

(57) ABSTRACT

The disclosure relates to a stencil mask, a method for manufacturing the stencil mask and use of the stencil mask in nanoscale device nanofabrication, including imprinting on substrates of deposition patterns for nanoscale devices. One embodiment relates to a stencil mask for manufacturing at least one nanoscale device on a substrate, the stencil mask comprising, a membrane having a top surface and bottom surface and a thickness therebetween of at least 500 nm, a predefined pattern of apertures extending through the membrane, each aperture having a width and a length in the top surface of the membrane, wherein at least the width and/or the length of one of said apertures is of less than 100 nm, each aperture defined by inner sidewalls extending between the top surface and the bottom surface of the membrane, and a set of separating nanostructures on the top surface of the membrane for separating the top surface of the membrane from a top surface of the substrate.

The disclosure relates to a stencil mask, a method for manufacturing the stencil mask and use of the stencil mask in nanoscale device nanofabrication, including imprinting on substrates of deposition patterns for nanoscale devices.

### BACKGROUND

Nanotechnology and nanofabrication research fields are key on the development of quantum computation, leading to improvements in the realization and performance of nowadays quantum bit (qubit) prototypes. Previous leaps on the fabrication of solid state qubits were led by the progress in nanofabrication tools. This allowed to perform cleaner, faster and more precise nanofabrication processes, improving the overall properties of qubits.

Typically, fabrication of qubit platforms used for solid state quantum computation require extreme environments. For this reason, ultra-high vacuum systems where pressure and temperature are controlled with high precision are used for deposition of materials and fabrication of qubits. For example, the growth of semiconductors is typically performed at temperatures of several hundreds of degrees Celsius whereas the deposition of metals range from cryogenic temperatures to also hundreds of degrees Celsius.

Stencil lithography is one of the techniques used for the selective fabrication of nanometer scale electronic and quantum devices. One of its advantages compared to conventional nanofabrication techniques is that it is an organic polymer resist-free technique, being able to fabricate devices in a cleaner way. Common device nanofabrication techniques imply the coating of the device host substrates with a layer of organic resist which will be exposed typically by electrons or photons in order to define device design prior to material deposition. Thereafter, the remaining resist needs to be removed typically by wet chemistry means, with the risk of leaving undesired pollutants on the surface of the substrate. Stencil mask lithography has the ability of directly depositing a desired material in a pattern defining a device. This fabrication technique ensures the cleanliness of the substrate throughout the fabrication process.

Previously disclosed stencil lithography masks comprise a thin membrane with thickness in the range of tenths of nm with an imprinted pattern of openings defined on it. By placing it over a substrate and evaporating a deposition material over it, only the material passing through the pattern of apertures will be deposited on the substrate, generating the material pattern of one or more devices below the mask. However, several inconveniencies arise by using this approach. The membrane is typically very fragile, single use and shows a relatively big height dispersion of the deposition due to the limited thickness.

### SUMMARY

Thus, there exist a need to address the problems of the stencil lithography masks known in the prior art, as will be presented herein.

A solution addressing the previous limitations can be achieved by means of a stencil mask, e.g. for manufacturing at least one nanoscale device on a substrate, the stencil mask comprising
a membrane having a top surface and bottom surface, preferably having a thickness between the top and bottom surfaces of at least 200 nm, preferably at least 500 nm, more preferably at least 1 μm, or even 1.5 or 2 μm,
a predefined pattern of apertures extending through the membrane, each aperture having a width and a length in the top surface of the membrane, preferably wherein at least the width and/or the length of one of said apertures is less than 500 nm, preferably less than 200 nm, most preferably less than 100 nm, possibly even less than 50 nm, each aperture defined by inner sidewalls extending between the top surface and the bottom surface of the membrane.

Preferably the mask also comprises one or more structural elements for separating the top surface of the membrane from a top surface of the substrate, for example a set of separating nanostructures on the top surface of the membrane.

Typically, said stencil mask comprises a membrane of Si, or other material compatible with nanofabrication processes. A main advantage of the presently disclosed stencil mask is the thickness the membrane, which can be at least an order of magnitude higher than membranes in usual stencil masks disclosed in the prior art, and still be used for accurately defining apertures extending through the membrane. Thereby the obtainable aspect ratio of apertures vs. membrane is very high. E.g. the aspect ratio defined as the minimum dimension of the aperture (e.g. width or length) in the plane of the membrane, relative to the membrane thickness. Hence the aspect ratio of the apertures relative to the thickness of the mask can be obtained by dividing the thickness of the mask by the width of an aperture. The obtainable aspect ratio of the presently disclosed stencil mask can be at least 2, preferably at least 5, more preferably at least 10, even more preferably at least 50, most preferably at least 100, possibly up to 200 or even above.

The present disclosure further relates to a method of manufacturing a stencil mask. Preferably, the herein disclosed stencil mask, aka hard stencil mask, can be fabricated via the Clean-Oxidize-Remove-Etch (CORE) nanofabrication process. Said process, allows to etch a pattern of apertures in Si or SiN substrates/membranes of a thickness >1 μm. The CORE nanofabrication process is capable of etching apertures of a width less than 10 nm, implying an ultra-high aspect ratio of the aperture width to membrane thickness of the presently disclosed stencil mask of at least 5, preferably at least 10,more preferably at least 50, most preferably at least 100, possibly up to 200 or above. It is the capability of defining ultra-high aspect ratio apertures what makes the CORE process suitable to fabricate hard stencil masks for lithography purposes.

The inner side walls of the apertures, e.g. defined via the CORE nanofabrication process, may have a line edge roughness of less than 10%, preferably less than 5% or even less than 2% relative to the (smallest) width of an aperture. I.e. substantially or completely smooth and scallop free. In addition, said inner sidewalls of the pattern of apertures might be fabricated parallel to each other and perpendicular to the plane of the mask, parallel to each other and not parallel to the plane of the mask, and not parallel to each other.

The present disclosure further relates to a method for manufacturing at least one nanoscale device pattern on a substrate by means of the presently disclosed stencil mask. In a preferred embodiment, a deposition material is evaporated over the hard stencil mask to define a pattern on a substrate placed underneath the mask. Due to the high aspect ratio of the apertures, only the material evaporated at an angle exactly aligned with the longitudinal extension of at least one of the walls of the aperture will be deposited at the surface of the underneath substrate. The present disclosure further relates to one or more nanoscale devices manufactured according to this method, such as qubits, semiconductor devices, superconductor devices, semiconductor-superconductor devices, any combination thereof or other quantum and not quantum devices for nano-electronic experiments.

Thus, with the herein disclosed stencil mask it is possible to overcome the fragility, angular resolution and reusability issues of prior art stencil masks.

### DESCRIPTION OF THE DRAWINGS

The present disclosure will in the following be described in greater detail with reference to the accompanying drawings:

FIG. 1 a schematic view of the steps of a fabrication process of a mask for stencil lithography, i.e. a hard stencil mask.

FIG. 2 scanning electron micrograph images of depositions of Al performed with the hard stencil mask on a substrate and schematic views of the evaporated material being blocked by the orientation of the walls of the hard stencil mask.

FIG. 3 a schematic view of a method of fabricating devices using stencil mask, comprising the steps of attaching and aligning a hard stencil mask onto a substrate, evaporating a series of deposition materials and detaching the mask from the substrate.

### DETAILED DESCRIPTION

### Hard Stencil Mask

In a preferred embodiment, the presently disclosed stencil mask for manufacturing nanoscale devices comprise a membrane having a top surface and bottom surface and a thickness therebetween of at least 200 nm, preferably at least 500 nm, more preferably at least 1 μm, or even 1.5 or 2 μm, a predefined pattern of apertures extending through the membrane, each aperture having a width and a length in the top surface of the membrane (and also in the bottom surface), wherein at least the (minimum) width and/or the (minimum) length of one of said apertures is of less than 200 nm, preferably less than 100 nm, more preferably less than 50 nm. Each aperture defined by inner sidewalls extending between the top surface and the bottom surface of the membrane, and a set of separating nanostructures on the top surface of the membrane for separating the top surface of the membrane from a top surface of the substrate.

Said separating nanostructures may be deployed along the hard stencil mask surface to allow a homogeneous distribution of pressure, weight and force exhorted on the substrate.

In a preferred embodiment of the present disclosure, the material composition of the mask is selected from the group of Si, SiN, SiGe and Ge. The cross-sectional shape of the apertures in the top and/or bottom surface of the membrane can be any shape, e.g. round, circular, elliptical, square, rectangular, triangular, pentagonal, etc. The width of the apertures can range between 10 nm and 1 μm, possibly up to 10 μm. The length of the apertures can range between 10 nm, or at least 500 nm, possibly up to 1 μm, or 10 μm or even up to 500 μm.

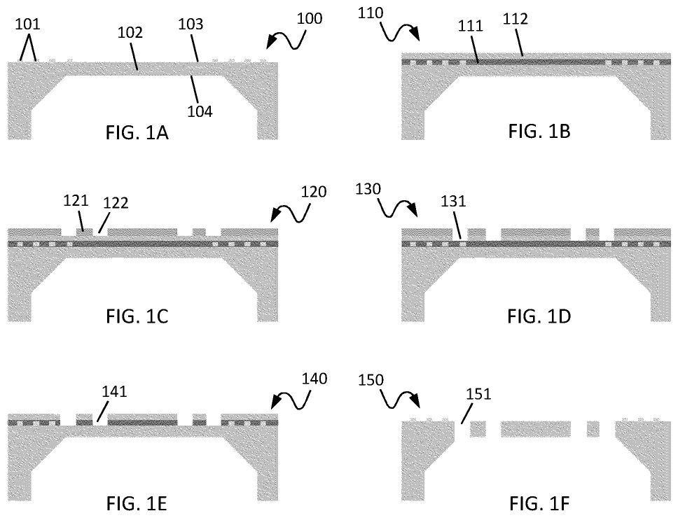

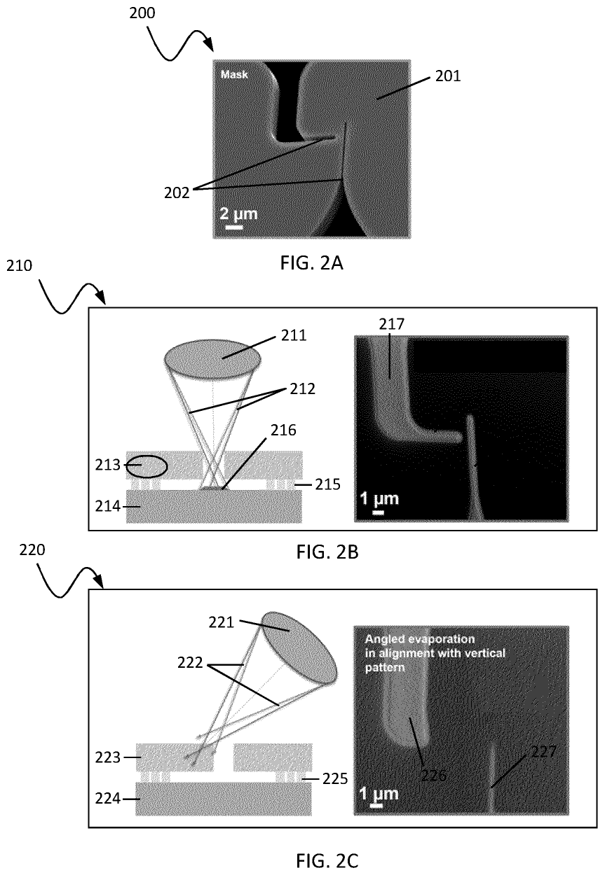

The aperture angle is used herein is defined as the angle formed between an extension of the inner sidewall of an aperture and the plane formed by the top surface of the membrane. At least one of the inner sidewalls of at least one of the apertures may define an angle of between 10 and 170 degrees, for example 90 degrees, with the top surface of the membrane. At least two of the inner walls of at least one of the apertures may be parallel to each other. Similarly at least two of the inner walls of at least one of the apertures are not parallel to each other. At least one of the apertures may be substantially cylindrical. At least one of the apertures may be tapered. At least one of the apertures may define an longitudinal extension through the membrane, and wherein this extension through the membrane is perpendicular to the top surface of the membrane (exemplified in FIGS. 1 and 2). At least one of the apertures may define an longitudinal extension through the membrane, and wherein this extension through the membrane forms and angle of between 10 and 90 with the top surface of the membrane.

A major advantage of the presently disclosed stencil mask is that least one (or all) of the inner side walls of at least one (or all) of the apertures can be made smooth. E.g. surface roughness of at least one of the inner sidewalls of the apertures may be below 10 nm, preferably below 5 nm, most preferably below 1 nm. Surface roughness understood here as either the maximum extension of the surface variation or the average extension of the surface variation. Another way to characterize surface roughness is the line edge roughness. The presently disclosed stencil mask can be realized with at least one pair of inner sidewalls of less than 20%, preferably less than 10%, most preferably less than 5%, or even less than 2% or less than 1%. This may be realized even for apertures of a (minimum) width of less than 100 nm. I.e. at least one of the inner sidewalls of the apertures may be substantially scallop-free. Scallop roughness is a known effect in this technical field and it may happen during known dry etching processes, wherein the inner sidewalls of defined apertures develop inner protrusions of nanometric size towards the inside of the of the substrate inside the aperture. The presently disclosed stencil mask can be realized with apertures with substantially scallop free inner side walls, even for thinner range of widths described before.

In one embodiment, at least one of the inner sidewalls of at least one of the apertures are not parallel to each other, e.g. positively or negatively tapered sidewalls, wherein the distance between the sidewalls at the beginning of the aperture is higher or smaller than the distance between the sidewalls at the end of the aperture, respectively. Thereby the size of the aperture of the top surface of the membrane might be different than the size of the corresponding aperture on the bottom surface of the membrane. Such sidewalls can be achieved by changing accordingly the fabrication parameters during the CORE process.

A set of separating nanostructures may comprise a set of nano-pillars, preferably arranged homogeneously on the top surface of the stencil mask membrane. The separating nanostructures are preferably separated by at least 1 μm from any aperture of the membrane. The material composition of the separating nanostructures may be selected from the group of Si, SiN, SiGe and Ge, or other ultra high vacuum, high vacuum or vacuum compatible material. Additionally, the separating nanostructures may be configured to separate the top surface of the membrane a fixed distance from the top surface of the substrate. This distance might range from 0 nm, the top surface of the stencil mask membrane effectively touching the substrate, to a distance up to tenths of μm or even hundreds of μm.

### Stencil Mask Fabrication

A preferred nanofabrication method of the herein disclosed stencil mask is the Clear-Oxidize-Remove-Etch (CORE) nanofabrication process. Said process allows to nanofabricate ultra-high aspect ratio features in semiconductor substrates of up to 200.

The fabrication process of one embodiment of a stencil lithography mask device as disclosed herein is shown in FIG. 1. A first blank Si mask 100 with no openings is provided, preferably of a thickness of 2 μm. The following detailed fabrication steps are not restricted to a particular thickness of the Si mask, which can range from 100 nm to several μm.

Said silicon mask has a set of nano-pillars 101 distributed homogeneously around the surface. Such nano-pillars may be comprised by SiOₓ, or other mechanically resistant material such as Si, SiGe, SiN or Ge. The nano-pillars might have a height, relatively with the height level of the mask where they are located 103, of 0 nm up to several μm. The nano-pillars are located in the substrate proximal surface 103 of the mask, being the opposite surface of the mask the distal surface of the mask 104.

In stencil mask nanofabrication, the CORE process is able to produce apertures in a Si membrane with smooth side walls at any width. This is particularly relevant when defining aperture patterns of small widths, such as <50 nm, being able to fabricate smooth side wall apertures with small or no line width roughness along the whole depth of the membrane comprising the mask. The strength of the CORE nanofabrication process relies in the capability of fabricating extremely thin apertures of <50 nm, in thick substrates of a thickness such as 2 μm or more, and having smooth scallop-free side walls.

In a first fabrication step of the stencil mask, shown in FIG. 1B, two layers comprised of 10 nm of Cr 111 and 10 nm of Si 112 are deposited on substrate proximal surface of the Si mask 110.

In a second fabrication step, shown in FIG. 1C, an additional layer of zep520 organic resist 121 is spin deposited on top of the previously deposited layers 120. A standard electron lithography exposure is performed on the resist, exposing only regions on the resist according to a predefined pattern. The exposed resist is developed, leaving a resist mask with the imprinted exposed pattern 122, on top of the Si layer underneath.

In the next fabrication step, shown in FIG. 1D, the deposited 10 nm layer of Si is etched, leaving exposed a pattern 131 of the deposited Cr layer underneath. Then, in FIG. 1E, the top layer of zep520 organic resist is stripped-off, as shown in the stencil mask 140 and the Cr is etched leaving an exposed pattern of the underneath Si 141 comprising the original mask.

In the last fabrication step, the CORE process is performed on the stencil mask 150, using comparable parameters than disclose in prior art. This creates a pattern of apertures 151 on the Si mask. The sidewalls of said apertures are smooth compared to other dry etch techniques, meaning that the roughness and the scallop size, typical from other similar dry etch processes, is less than 5 nm and scallop-effect free. Finally, the remaining Cr on the surface of the Si mask is removed, leaving a clean Si stencil mask with a pattern of apertures.

A configuration of the sidewalls on each aperture can be designed by adjusting the fabrication parameters of the CORE process. In an embodiment, a pair of sidewalls defining the apertures are parallel to each other. This implies that the aperture crosses the thickness of the Si mask, perpendicular to the plane of the surface of the mask.

A property of the CORE process compared to other fabrication methods is the ability of generating a pattern of ultra-high aspect ratio thin apertures, as small as 10 nm, in a membrane of high thickness, at least >1 μm, while having smooth side walls. Typical membrane thicknesses disclosed in prior art works imply a thickness typically much smaller than 1 μm, however, a person skilled in art would understand that the definition of membrane of the embodiment herein disclosed is used due to the similarities, but does not imply a thickness <1 μm.

### Method for Manufacturing Devices

The present disclosure further relates to a method for manufacturing at least one nanoscale device pattern on a substrate. The method in one embodiment comprises the steps of providing at least one of the presently disclosed stencil masks, attaching and aligning the top surface of the membrane of the stencil mask on a top surface of the substrate with respect to a deposition material source, evaporating at least a first type of deposition material over the stencil mask, such that at least a first nanoscale device pattern is generated on the top surface of the substrate in accordance with at least a first part of the predefined pattern of apertures in the membrane. Then optionally evaporating at least a second type of deposition material over the stencil mask, such that at least a second nanoscale device pattern is generated on the top surface of the substrate in accordance with at least a second part of the predefined pattern of apertures in the membrane. The first and second type of deposition material can be the same or different materials. This deposition process can be repeated for different or the same material, until the wanted nanoscale device pattern is obtained. I.e. the evaporation steps can be repeated more than one time for one stencil mask.

The disclosed method of manufacturing method allows to fabricate multi-stack layers of material without the necessity of breaking the ultra-high vacuum along the process. For example, complementary steps such as oxidation, annealing, metallization or ion implantation may be performed between material deposition steps. Hence, it is possible to fabricate complex stacks of materials with a single stencil mask and varying the deposition angles accordingly to the fabricated pattern.

Another advantage of the presently disclosed stencil mask is that the stencil mask may be reversibly attached to the substrate, and that the evaporated deposition material can be removed from the stencil mask such that the stencil mask is reusable. The evaporated deposition material on the mask can for example be removed via selective wet etch. The deposition of materials may be performed in a series of steps ordered such that the removal of remaining material can be done by etching techniques. The deposition of materials may be performed at a deposition rate, temperature and vacuum chamber pressure such that the removal of remaining material is performed by etching or thermal annealing processes.

A spatial positioning of at least one source of the at least first and/or second deposition material may be controlled to define a deposition material angle with respect to the bottom surface of the membrane. In that regard, the deposition material angle may at least partly define the at least one nanoscale device pattern deposited through the pattern of apertures in the membrane.

An angular dispersion of the evaporated deposition material on the top surface of the substrate may be determined by the aspect ratio between the thickness of the membrane of the stencil mask, the width of the apertures in the pattern and the separation distance between the top surface of the membrane and the top surface of the substrate. In addition, the angular dispersion of the evaporated deposition material may be determined by the height of the nano-pillars located in the substrate proximal surface, wherein an increase of the height induce a higher angular dispersion of the deposition material. At a height of the nano-pillars equal to 0 nm, the angular dispersion is supressed and the defined pattern is directly imprinted onto the surface of the substrate.

In another preferred embodiment of a fabricated stencil mask 201, shown in FIG. 2A, due to the high aspect ratio of the fabricated apertures 202, the evaporated deposition material can be blocked by a sidewall of an aperture if the evaporating material source is not aligned with the aperture. FIG. 2B shows an evaporation example 210 wherein the source, mask and substrate are aligned. An evaporating source 211 evaporates at least a material onto the mask with a certain angular dispersion defined by the maximum angle of evaporated material 212 allowed through the opening of a stencil mask 213. A deposition 216 is created on the underneath substrate 214, which is separated a distance due to the nano-pillars 215. The SEM image in FIG. 2B shows a deposition 217, 218 and 219 of a material by using a stencil mask, according to the mask shown in FIG. 2A.

FIG. 2C shows an evaporation example 220 wherein the source, mask and substrate are not aligned. An evaporating source 221 evaporates at least a material onto the mask with a certain angular dispersion defined by the maximum angle of evaporated material 212 allowed through the opening of a stencil mask 223. In this case, due to the high aspect ratio of the apertures and the relative orientation of the evaporating source with respect to the stencil mask, the material deposition at this angle is blocked by the stencil mask 223 and no material reaches the substrate 224. This example uses an embodiment of an stencil mask with the same nano-pillar separation 225 as the case shown in FIG. 2B. The SEM image in FIG. 2C shows a deposition of a material 226 and 227 by using a stencil mask. Only the apertures on the mask that generated the depositions 226 and 227 were aligned with the source of material evaporation.

Opposed to the case shown in FIG. 2B, in FIG. 2C apertures of the central part of the design was not aligned with the mask, leading to an effective blockade of material only due to the misalignment of the mask with respect to the evaporation source. A second source of material, comprising the same or different elements, might be evaporated in the aligned configuration of the mask to create additional depositions without the necessity of exchanging the mask.

In yet another preferred embodiment, the stencil mask might be mostly chemically stable to wet etch agents reactive to the materials evaporated from the sources. As material is evaporated over the mask, the thinnest apertures might suffer clogging, stopping any further material deposition through the mask. By submerging the mask on a wet etchant, the metal might be removed and the mask might be used in additional depositions.

A typical material deposition using the disclosed stencil mask might comprise an amount of evaporating material not enough to clog the apertures.

A series of typical material depositions using the disclosed stencil mask might be performed at a different deposition rate, depending on the properties of the material to be evaporated, the desired crystal quality of the deposited layer of material or the thickness of the apertures in the stencil mask.

A series of typical material depositions using the disclosed stencil mask might be performed at a different temperature, depending on the properties of the material to be evaporated, the desired crystal quality of the deposited layer of material or the thickness of the apertures in the stencil mask.

A series of different material depositions might be deposited using the same stencil mask, each deposition at a different alignment orientation of the evaporation source with respect to the mask and substrate, allowing to imprint different patterns within the same system of stencil mask and substrate.

The patterns to be imprinted onto the surface of the substrate may be designed accordingly and taking into account the variables that affect their deposition. A series of deposition steps, each step performed at different temperature, pressure, mask orientation and others parameters may be performed until a desired full stack of materials is fabricated.

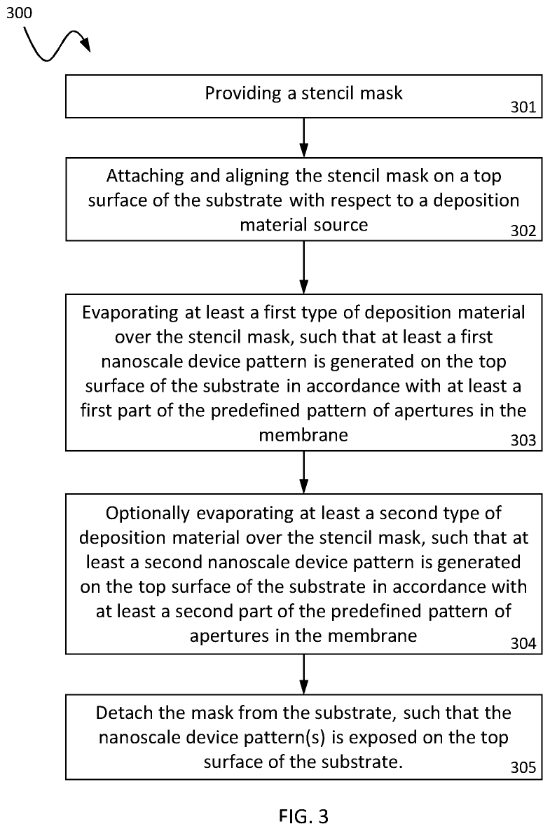

FIG. 3 shows a method 300 of for manufacturing at least one nanoscale device on a substrate, the stencil mask comprising the steps: providing a stencil mask 301, attaching and aligning the stencil mask on a top surface of the substrate with respect to a deposition material source 302, evaporating at least a first type of deposition material over the stencil mask, such that at least a first nanoscale device pattern is generated on the top surface of the substrate in accordance with at least a first part of the predefined pattern of apertures in the membrane 303, optionally evaporating at least a second type of deposition material over the stencil mask, such that at least a second nanoscale device pattern is generated on the top surface of the substrate in accordance with at least a second part of the predefined pattern of apertures in the membrane 304, and detach the mask from the substrate, such that the nanoscale device pattern(s) is exposed on the top surface of the substrate.

### Items

1. A stencil mask for manufacturing at least one nanoscale device on a substrate, the stencil mask comprising,
   a. a membrane having a top surface and bottom surface and a thickness therebetween of at least 200 nm, preferably at least 500 nm, more preferably at least 1 μm, or even 1.5 or 2 μm,
   b. a predefined pattern of apertures extending through the membrane, each aperture having a width and a length in the top surface of the membrane, wherein at least the width and/or the length of one of said apertures is of less than 100 nm, each aperture defined by inner sidewalls extending between the top surface and the bottom surface of the membrane, and
   c. a set of separating nanostructures on the top surface of the membrane for separating the top surface of the membrane from a top surface of the substrate.
2. The stencil mask according to item 1, wherein the material composition of the mask is selected from the group of Si, SiN, SiGe and Ge.
3. The stencil mask according to any of the preceding items, wherein an aspect ratio between the thickness of the membrane and the width of the pattern features is at least 2, preferably at least 5, more preferably at least 10, most preferably at least 50, possibly up to 200.
4. The stencil mask according to any of the preceding items, wherein the width of the apertures is at least 10 nm, possibly up to 10 μm.
5. The stencil mask according to any of the preceding items, wherein the length of the apertures is at least 10 nm, or at least 500 nm, possibly up to 500 μm.
6. The stencil mask according to any of the preceding items, wherein the apertures in the membrane are defined by the Clear-Oxidize-Remove-Etch nanofabrication process.
7. The stencil mask according to any of the preceding items, wherein at least one of the inner sidewalls of at least one of the apertures define an angle of between 10 and 170 degrees with the top surface of the membrane.
8. The stencil mask according to any of the preceding items, wherein at least two of the inner sidewalls of at least one of the apertures are parallel to each other.
9. The stencil mask according to any of the preceding items, wherein at least two of the inner sidewalls of at least one of the apertures are not parallel to each other.
10. The stencil mask according to any of the preceding items, wherein at least one of the apertures is substantially cylindrical.
11. The stencil mask according to any of the preceding items, wherein at least one of the apertures is tapered.
12. The stencil mask according to any of the preceding items, wherein at least one of the apertures define a longitudinal extension through the membrane, and wherein this extension through the membrane is perpendicular to the top surface of the membrane.
13. The stencil mask according to any of the preceding items, wherein at least one of the apertures define an longitudinal extension through the membrane, and wherein this extension through the membrane forms and angle of between 10 and 90 with the top surface of the membrane.
14. The stencil mask according to any of the preceding items, wherein at least one of the inner side walls of the apertures are smooth.
15. The stencil mask according to any of the preceding items, wherein a surface roughness of at least one of the inner sidewalls of the apertures is below 5 nm.
16. The stencil mask according to any of the preceding items, wherein at least one of the inner sidewalls of the apertures is substantially scallop-free.
17. The stencil mask according to any of the preceding items, wherein a line edge roughness of at least one pair of inner sidewalls of at least one of the apertures is less than 20%, preferably less than 10%, most preferably less than 5%.
18. The stencil mask according to any of the preceding items, wherein a line edge roughness of at least one pair of inner sidewalls of at least one of the apertures width a of less than 100 nm, is less than 20%, preferably less than 10%, most preferably less than 5%.
19. The stencil mask according to any of the preceding items, wherein the separating nanostructures comprise a set of nano-pillars, preferably arranged homogeneously on the top surface of the membrane.
20. The stencil mask according to any of the preceding items, wherein the separating nanostructures are separated at least 1 μm from any aperture of the membrane.
21. The stencil mask according to any of the preceding items, wherein the material composition of the separating nanostructures is selected from the group of Si, SiN, SiGe and Ge.
22. The stencil mask according to any of the preceding items, wherein the separating nanostructures are configured to separate the surface of the membrane a fixed distance from the surface of the substrate.
23. A method for manufacturing at least one nanoscale device pattern on a substrate comprising the steps of:
   a. providing a stencil mask,
   b. attaching and aligning the stencil mask on a top surface of the substrate with respect to a deposition material source,
   c. evaporating at least a first type of deposition material over the stencil mask, such that at least a first nanoscale device pattern is generated on the top surface of the substrate in accordance with at least a first part of the predefined pattern of apertures in the membrane,
   d. optionally evaporating at least a second type of deposition material over the stencil mask, such that at least a second nanoscale device pattern is generated on the top surface of the substrate in accordance with at least a second part of the predefined pattern of apertures in the membrane, and
   e. detach the mask from the substrate, such that the nanoscale device pattern(s) is exposed on the top surface of the substrate.
24. The method according to item 23, wherein the stencil mask is fabricated via a Clear-Oxidize-Remove-Etch (CORE) nanofabrication process.
25. The method according to any of items 23-24, further comprising a step of removing the evaporated deposition material from the stencil mask such that the stencil mask is reusable.
26. The method according to any of items 23-25, wherein a spatial positioning of at least one source of the at least first and/or second deposition material is controlled to define a deposition material angle with respect to the bottom surface of the membrane.
27. The method according to item 26, wherein the deposition material angle at least partly defines the at least one nanoscale device pattern deposited through the pattern of apertures in the membrane.
28. The method according to any of items 23-27, wherein an angular dispersion of the evaporated deposition material on the top surface of the substrate is determined by the aspect ratio between the thickness of the membrane of the stencil mask, the width of the apertures in the pattern and the separation distance between the top surface of the membrane and the top surface of the substrate.
29. The method according to any of items 23-28, wherein the mask is reversibly attached to the substrate.
30. The method according to any of items 25-29, wherein the evaporated deposition material on the mask is removed via selective wet etch.
31. The method according to any of items 23-30, wherein the evaporation steps are repeated more than one time for one stencil mask.
32. The method according to any of items 23-31, wherein the stencil mask is the stencil mask according to any of items 1-22.

1. A stencil mask for manufacturing at least one nanoscale device on a substrate, the stencil mask comprising,
a membrane having a top surface and a bottom surface and a thickness therebetween of at least 500 nm,
a predefined pattern of apertures extending through the membrane, each aperture having a width and a length in the top surface of the membrane, wherein at least the width and/or the length of one of said apertures is less than 100 nm, each aperture defined by inner sidewalls extending between the top surface and the bottom surface of the membrane, and
a set of separating nanostructures on the top surface of the membrane for separating the top surface of the membrane from a top surface of the substrate.

2. The stencil mask according to claim 1, wherein the material composition of the mask is selected from the group of Si, SiN, SiGe and Ge.

3. The stencil mask according to claim 1, wherein an aspect ratio between the thickness of the membrane and the width of at least one of the apertures is at least 5.

4. The stencil mask according to claim 1, wherein the thickness of the membrane is at least 500 nm, or at least 1 μm, more preferably or at least 2 μm, or even more preferably at least 5 μm.

5. The stencil mask according to any of the preceding claims claim 1, wherein the width of the apertures is at least 10 nm, possibly or up to 10 μm.

6. The stencil mask according to claim 1, wherein the length of the apertures is at least 10 nm, or at least 500 nm, possibly-or up to 500 μm.

7. The stencil mask according to claim 1, wherein the apertures in the membrane are defined by the Clear-Oxidize-Remove-Etch nanofabrication process.

8. The stencil mask according to claim 1, wherein at least one of the inner sidewalls of at least one of the apertures define an angle of between 10 and 170 degrees with the top surface of the membrane.

9. The stencil mask according to claim 1, wherein at least two of the inner sidewalls of at least one of the apertures are parallel to each other.

10. The stencil mask according to claim 1, wherein the inner sidewalls of at least one of the apertures are substantially smooth and scallop free.

11. The stencil mask according to claim 1, wherein a surface roughness of at least one of the inner sidewalls of the apertures is below 5 nm.

12. The stencil mask according to claim 1, wherein the set of separating nanostructures are configured to separate the surface of the membrane a fixed distance from the surface of the substrate.

13. The stencil mask according to claim 1, wherein the set of separating nanostructures comprise a set of nano-pillars,
preferably arranged homogeneously on the top surface of the membrane.

14. The stencil mask according to claim 1, wherein the set of separating nanostructures are separated at least 1 μm from any aperture of the membrane.

15. The stencil mask according to claim 1, wherein the material composition of the separating nanostructures is selected from the group of Si, SiOₓ, SiN, SiGe and Ge.

16. A method for manufacturing at least one nanoscale device pattern on a substrate comprising the steps of:
a. providing a stencil mask,
b. attaching and aligning the mask on a top surface of the substrate with respect to a deposition material source, such that the separating nanostructure separate the top surface of the membrane of the mask from the top surface of the substrate,
c. evaporating at least a first type of deposition material over the stencil mask, such that at least a first nanoscale device pattern is generated on the top surface of the substrate in accordance with at least a first part of the predefined pattern of apertures in the membrane,
d. optionally evaporating at least a second type of deposition material over the stencil mask, such that at least a second nanoscale device pattern is generated on the top surface of the substrate in accordance with at least a second part of the predefined pattern of apertures in the membrane, and
e. detach the mask from the substrate, such that the nanoscale device pattern(s) is exposed on the top surface of the substrate.

17. The method according to claim 16, further comprising a step of removing the evaporated deposition material from the stencil mask such that the stencil mask is reusable.

18. The method according to claim 16, wherein a spatial positioning of at least one source of the at least first and/or second deposition material is controlled to define a deposition material angle with respect to the bottom surface of the membrane.

19. The method according to claim 16, wherein an angular dispersion of the evaporated deposition material on the top surface of the substrate is determined by the aspect ratio between the thickness of the membrane of the stencil mask, the width of the apertures in the pattern and the separation distance between the top surface of the membrane and the top surface of the substrate.

20. The method according to claim 16, wherein the mask is reversibly attached to the substrate.
